(19) United States
(12) Patent Application Publication
(10) Pub. No.: US 2024/0268131 A1
(43) Pub. Date: Aug. 8, 2024

(54) OPTICAL SIGNALING FOR STACKED MEMORY DEVICE ARCHITECTURES

(71) Applicant: Micron Technology, Inc., Boise, ID (US)

(72) Inventors: Timothy M. Hollis, Meridian, ID (US); Eric J. Stave, Meridian, ID (US)

(21) Appl. No.: 18/404,569

(22) Filed: Jan. 4, 2024

Related U.S. Application Data
(60) Provisional application No. 63/442,805, filed on Feb. 2, 2023.

(51) Int. Cl. H10B 80/00; H01L 25/065

(52) U.S. Cl. CPC H10B 80/00; H01L 25/0657; H01L 2225/06534; H01L 2225/06541

(57) ABSTRACT

Methods, systems, and devices for near memory photonics are described. A memory device may include an optical interface, which may include an array of optical emitters and optical receivers, to convert between electrical signaling and optical signaling. For example, a vertical stack of memory dies may be coupled with an interface component which includes the optical interface. Optical signaling may be carried over one or more optical channels to a host device, and the host device may include an optical interface to convert the optical signaling back to electrical signaling. In some examples, the interface component may be positioned above the vertical stack of memory dies. Alternatively, the interface component may be positioned below the stack of memory dies, and may extend horizontally beyond the stack of memory dies, forming a porch section. In such cases, the optical interface may be distributed across the porch section.

### CROSS REFERENCE

The present Application for Patent claims priority to and the benefit of U.S. Provisional Application No. 63/442,805 by Hollis et al., entitled “OPTICAL SIGNALING FOR STACKED MEMORY DEVICE ARCHITECTURES,” filed Feb. 2, 2023, assigned to the assignee hereof, and is expressly incorporated by reference in its entirety herein.

### FIELD OF TECHNOLOGY

The following relates to one or more systems for memory, including near memory photonics.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, a component may read (e.g., sense, detect, retrieve, identify, determine, evaluate) a stored state in the memory device. To store information, a component may write (e.g., program, set, assign) the state in the memory device.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 illustrates an example of a system that supports near memory photonics in accordance with examples as disclosed herein.

FIG. 2 illustrates an example of a memory die that supports near memory photonics in accordance with examples as disclosed herein.

FIGS. 3A and 3B illustrate examples of systems that support near memory photonics in accordance with examples as disclosed herein.

FIG. 4 illustrates an example of a system that supports near memory photonics in accordance with examples as disclosed herein.

FIGS. 5 through 7 illustrate examples of stacks of memory dies that support near memory photonics in accordance with examples as disclosed herein.

### DETAILED DESCRIPTION

In some systems, a host device and one or more memory systems may implement electrical interfaces to electrically communicate signaling (e.g., commands and data) using one or more conductive channels between the memory systems and the host device. In some cases, each memory system may include one or more memory dies arranged in a vertical stack on a substrate. Each vertical stack of memory dies may have an associated interface component (e.g., a buffer component) that may include bond pads for connecting an electrical interface when installed in the system. In some cases, a manufacturer of the memory system may perform one or more functional tests of the memory system prior to integrating the memory system with the host device. However, in some cases attaching a testing probe to the electrical interface (e.g., bond pads) may damage the electrical interface, for example by creating witness marks from contact with the testing probe. The witness marks may substantially reduce reliability of attaching bond wires. Thus, testing of the memory dies may instead be performed using side channels external to the electrical interface, which may limit the speed of testing, as well as limiting testing of the electrical interface itself. Additionally, due to signal loss over conductive channels, architecture of such systems may be limited to relatively short conductive channels of a same or similar length between the host device and memory systems, which may reduce potential memory density.

As described herein, a memory system may include an optical interface to convert between electrical signaling and optical signaling. For example, a set of memory dies may be stacked vertically above a substrate, and may be coupled with an interface component (e.g., a buffer layer) which includes the optical interface. The optical interface may include an array of optical receivers and optical emitters, which may convert electrical signaling from a set of channels of each memory die to optical signaling. The optical signaling may be carried over one or more optical channels to the host device, and the host device may include an optical interface to convert the optical signaling back to electrical signaling. Similarly, the optical interface may receive optical signaling from the host device over the optical channels, and convert the optical signaling to electrical signaling. In some examples, the stack of memory dies may include a set of optical vias, each optical via extending vertically through a respective subset of the memory dies to couple (e.g., optically couple) a memory die with the interface component.

In some examples, the interface component may be positioned above the vertical stack of memory dies, and the optical interface may be distributed across the upper surface of the interface component. Alternatively, the interface component may be positioned below the stack of memory dies (e.g., between the stack of memory dies and the substrate), and may extend horizontally beyond the stack of memory dies, forming a porch section. In such cases, the optical interface may be distributed across an upper surface of the porch section. Such architectures may allow for full functional, at-speed testing of the memory system using the native interface (e.g., the optical interface), for example by using an optical testing probe positioned above the optical interface.

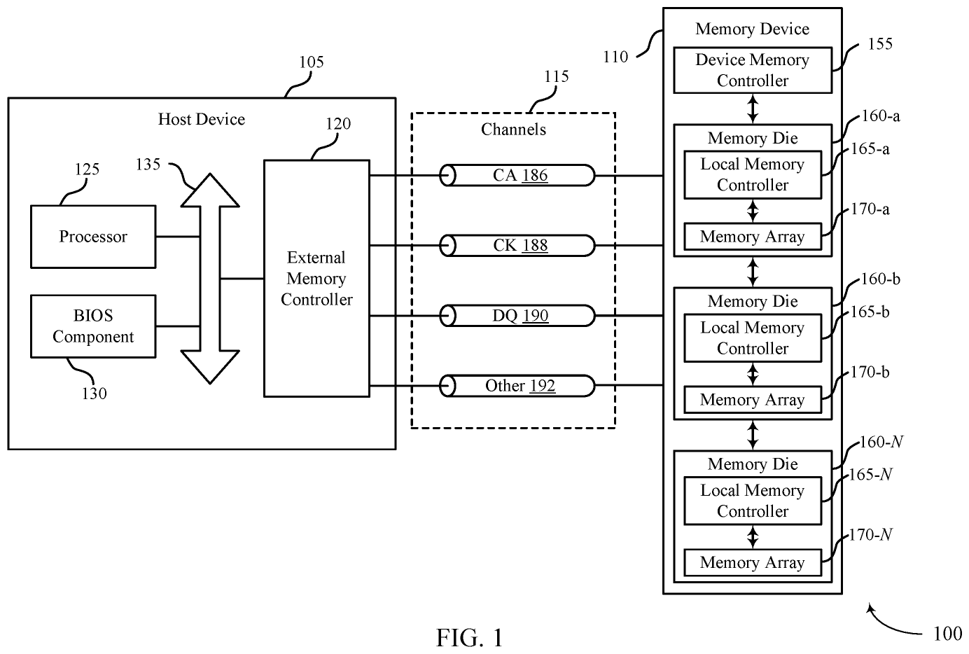

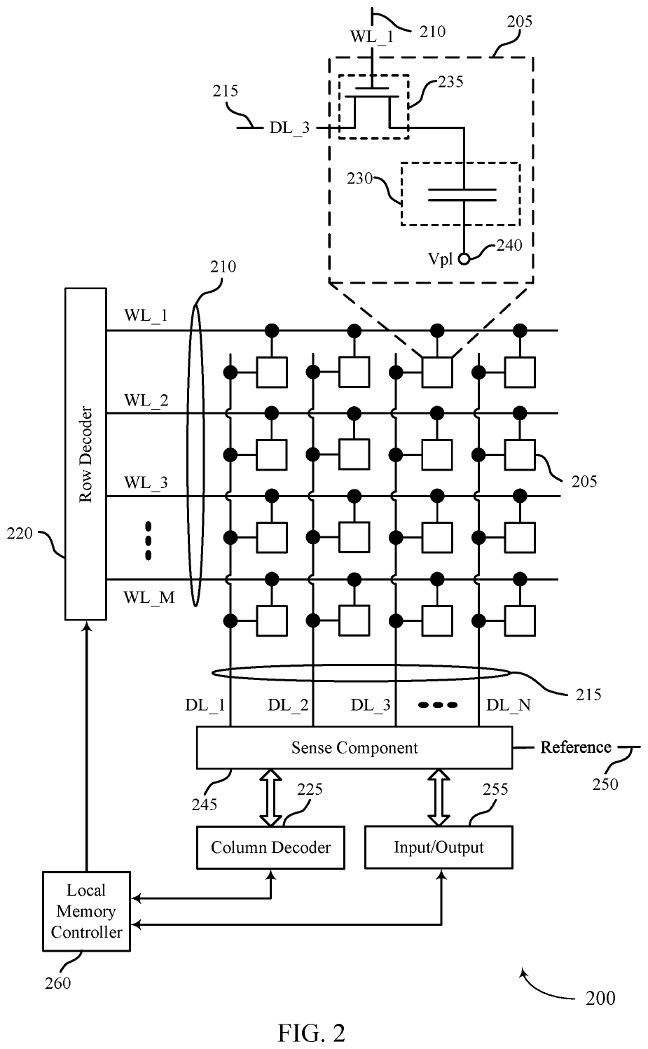

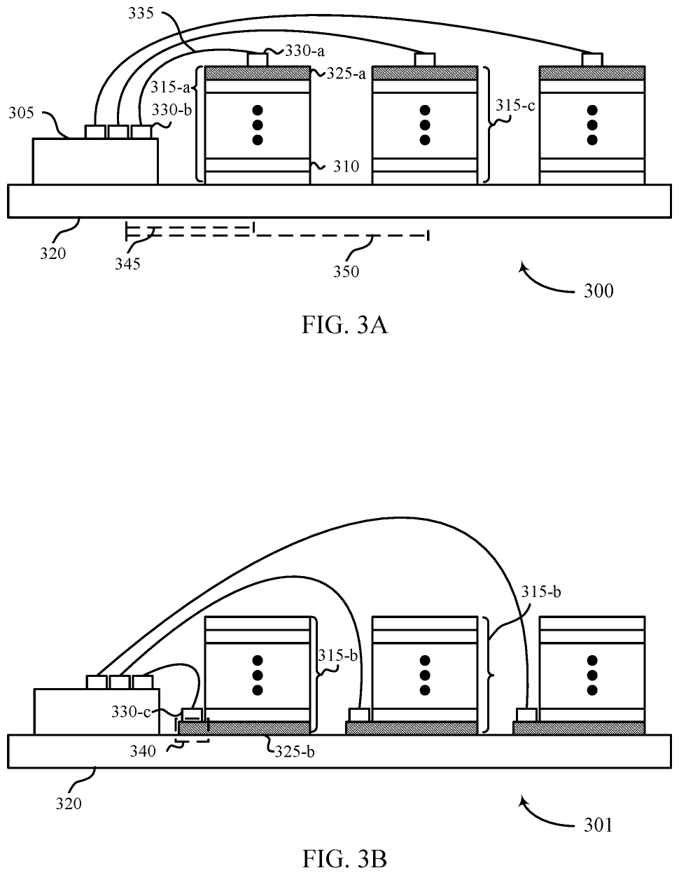

Features of the disclosure are initially described in the context of systems and dies as described with reference to FIGS. 1 and 2. Features of the disclosure are described in the context of systems and stacks of memory dies as described with reference to FIGS. 3A through 7.

FIG. 1 illustrates an example of a system 100 that supports near memory photonics in accordance with examples as disclosed herein. The system 100 may include a host device 105, a memory device 110, and a plurality of channels 115 coupling the host device 105 with the memory device 110. The system 100 may include one or more memory devices 110, but aspects of the one or more memory devices 110 may be described in the context of a single memory device (e.g., memory device 110).

The system 100 may include portions of an electronic device, such as a computing device, a mobile computing device, a wireless device, a graphics processing device, a vehicle, or other systems. For example, the system 100 may illustrate aspects of a computer, a laptop computer, a tablet computer, a smartphone, a cellular phone, a wearable device, an internet-connected device, a vehicle controller, or the like. The memory device 110 may be a component of the system 100 that is operable to store data for one or more other components of the system 100.

Portions of the system 100 may be examples of the host device 105. The host device 105 may be an example of a processor (e.g., circuitry, processing circuitry, a processing component) within a device that uses memory to execute processes, such as within a computing device, a mobile computing device, a wireless device, a graphics processing device, a computer, a laptop computer, a tablet computer, a smartphone, a cellular phone, a wearable device, an internet-connected device, a vehicle controller, a system on a chip (SoC), or some other stationary or portable electronic device, among other examples. In some examples, the host device 105 may refer to the hardware, firmware, software, or any combination thereof that implements the functions of an external memory controller 120. In some examples, the external memory controller 120 may be referred to as a host (e.g., host device 105).

A memory device 110 may be an independent device or a component that is operable to provide physical memory addresses/space that may be used or referenced by the system 100. In some examples, a memory device 110 may be configurable to work with one or more different types of host devices. Signaling between the host device 105 and the memory device 110 may be operable to support one or more of: modulation schemes to modulate the signals, various pin configurations for communicating the signals, various form factors for physical packaging of the host device 105 and the memory device 110, clock signaling and synchronization between the host device 105 and the memory device 110, timing conventions, or other functions.

The memory device 110 may be operable to store data for the components of the host device 105. In some examples, the memory device 110 (e.g., operating as a secondary-type device to the host device 105, operating as a dependent-type device to the host device 105) may respond to and execute commands provided by the host device 105 through the external memory controller 120. Such commands may include one or more of a write command for a write operation, a read command for a read operation, a refresh command for a refresh operation, or other commands.

The host device 105 may include one or more of an external memory controller 120, a processor 125, a basic input/output system (BIOS) component 130, or other components such as one or more peripheral components or one or more input/output controllers. The components of the host device 105 may be coupled with one another using a bus 135.

The processor 125 may be operable to provide functionality (e.g., control functionality) for the system 100 or the host device 105. The processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination of these components. In such examples, the processor 125 may be an example of a central processing unit (CPU), a graphics processing unit (GPU), a general purpose GPU (GPGPU), or an SoC, among other examples. In some examples, the external memory controller 120 may be implemented by or be a part of the processor 125.

The BIOS component 130 may be a software component that includes a BIOS operated as firmware, which may initialize and run various hardware components of the system 100 or the host device 105. The BIOS component 130 may also manage data flow between the processor 125 and the various components of the system 100 or the host device 105. The BIOS component 130 may include instructions (e.g., a program, software) stored in one or more of read-only memory (ROM), flash memory, or other non-volatile memory.

In some examples, the system 100 or the host device 105 may include an I/O controller. An I/O controller may manage data communication between the processor 125 and the peripheral component(s) (e.g., input devices, output devices). The I/O controller may manage peripherals that are not integrated into or with the system 100 or the host device 105. In some examples, the I/O controller may represent a physical connection (e.g., one or more ports) with external peripheral components.

In some examples, the system 100 or the host device 105 may include an input component, an output component, or both. An input component may represent a device or signal external to the system 100 that provides information (e.g., signals, data) to the system 100 or its components. In some examples, and input component may include an interface (e.g., a user interface or an interface between other devices). In some examples, an input component may be a peripheral that interfaces with system 100 via one or more peripheral components or may be managed by an I/O controller. An output component may represent a device or signal external to the system 100 operable to receive an output from the system 100 or any of its components. Examples of an output component may include a display, audio speakers, a printing device, another processor on a printed circuit board, and others. In some examples, an output may be a peripheral that interfaces with the system 100 via one or more peripheral components or may be managed by an I/O controller.

The memory device 110 may include a device memory controller 155 and one or more memory dies 160 (e.g., memory chips) to support a capacity (e.g., a desired capacity, a specified capacity) for data storage. Each memory die 160 (e.g., memory die 160-a, memory die 160-b, memory die 160-N) may include a local memory controller 165 (e.g., local memory controller 165-a, local memory controller 165-b, local memory controller 165-N) and a memory array 170 (e.g., memory array 170-a, memory array 170-b, memory array 170-N). A memory array 170 may be a collection (e.g., one or more grids, one or more banks, one or more tiles, one or more sections) of memory cells, with each memory cell being operable to store one or more bits of data. A memory device 110 including two or more memory dies 160 may be referred to as a multi-die memory or a multi-die package or a multi-chip memory or a multi-chip package.

A memory die 160 may be an example of a two-dimensional (2D) array of memory cells or may be an example of a three-dimensional (3D) array of memory cells. In some examples, a 2D memory die 160 may include a single memory array 170. In some examples, a 3D memory die 160 may include two or more memory arrays 170, which may be stacked on top of one another or positioned next to one another (e.g., relative to a substrate). In some examples, memory arrays 170 in a 3D memory die 160 may be referred to as or otherwise include different sets (e.g., decks, levels, layers, dies). A 3D memory die 160 may include any quantity of stacked memory arrays 170 (e.g., two high, three high, four high, five high, six high, seven high, eight high). In some 3D memory dies 160, different decks may share a common access line such that some decks may share one or more of a word line, a digit line, or a plate line.

The device memory controller 155 may include components (e.g., circuitry, logic) operable to control operation of the memory device 110. The device memory controller 155 may include hardware, firmware, or instructions that enable the memory device 110 to perform various operations and may be operable to receive, transmit, or execute commands, data, or control information related to the components of the memory device 110. The device memory controller 155 may be operable to communicate with one or more of the external memory controllers 120, the one or more memory dies 160, or the processor 125. In some examples, the device memory controller 155 may control operation of the memory device 110 described herein in conjunction with the local memory controller 165 of the memory die 160.

A local memory controller 165 (e.g., local to a memory die 160) may include components (e.g., circuitry, logic) operable to control operation of the memory die 160. In some examples, a local memory controller 165 may be operable to communicate (e.g., receive or transmit data or commands or both) with the device memory controller 155. In some examples, a memory device 110 may not include a device memory controller 155, and a local memory controller 165 or the external memory controller 120 may perform various functions described herein. As such, a local memory controller 165 may be operable to communicate with the device memory controller 155, with other local memory controllers 165, or directly with the external memory controller 120, or the processor 125, or any combination thereof. Examples of components that may be included in the device memory controller 155 or the local memory controllers 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, or various other components operable for supporting described operations of the device memory controller 155 or local memory controller 165 or both.

The external memory controller 120 may be operable to enable communication of information (e.g., data, commands, or both) between components of the system 100 (e.g., between components of the host device 105, such as the processor 125, and the memory device 110). The external memory controller 120 may process (e.g., convert, translate) communications exchanged between the components of the host device 105 and the memory device 110. In some examples, the external memory controller 120, or other component of the system 100 or the host device 105, or its functions described herein, may be implemented by the processor 125. For example, the external memory controller 120 may be hardware, firmware, or software, or some combination thereof implemented by the processor 125 or other component of the system 100 or the host device 105. Although the external memory controller 120 is depicted as being external to the memory device 110, in some examples, the external memory controller 120, or its functions described herein, may be implemented by one or more components of a memory device 110 (e.g., a device memory controller 155, a local memory controller 165) or vice versa.

The components of the host device 105 may exchange information with the memory device 110 using one or more channels 115. The channels 115 may be operable to support communications between the external memory controller 120 and the memory device 110. Each channel 115 may be an example of a transmission medium that carries information between the host device 105 and the memory device 110. Each channel 115 may include one or more signal paths (e.g., a transmission medium, a conductor) between terminals associated with the components of the system 100. A signal path may be an example of a conductive path operable to carry a signal. For example, a channel 115 may be associated with a first terminal (e.g., including one or more pins, including one or more pads) at the host device 105 and a second terminal at the memory device 110. A terminal may be an example of a conductive input or output point of a device of the system 100, and a terminal may be operable to act as part of a channel.

Channels 115 (and associated signal paths and terminals) may be dedicated to communicating one or more types of information. For example, the channels 115 may include one or more command and address (CA) channels 186, one or more clock signal (CK) channels 188, one or more data (DQ) channels 190, one or more other channels 192, or any combination thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols (e.g., signal levels) of a signal may be registered for each clock cycle (e.g., on both a rising edge and a falling edge of a clock signal).

In some cases, a memory device 110 may include an optical interface to convert between electrical signaling and optical signaling. For example, a set of memory dies 160 may be stacked vertically above a substrate, and may be coupled with an interface component which includes the optical interface. The optical interface may include an array of optical receivers and optical emitters, which may convert electrical signaling from a set of channels of each memory die 160 to optical signaling. The optical signaling may be carried over one or more optical channels (e.g., channels 115) to a host device 105, and the host device 105 may include an optical interface to convert the optical signaling back to electrical signaling. Similarly, the optical interface may receive optical signaling from the host device 105 over the optical channels, and convert the optical signaling to electrical signaling. In some examples, the stack of memory dies 160 may include a set of optical vias, each optical via extending vertically through a respective subset of the memory dies to couple (e.g., optically couple) a memory die with the interface component.

In some examples, the interface component may be positioned above the vertical stack of memory dies 160, and the optical interface may be distributed across the upper surface of the interface component. Alternatively, the interface component may be positioned below the stack of memory dies 160 (e.g., between the stack of memory dies and the substrate), and may extend horizontally beyond the stack of memory dies, forming a porch section. In such cases, the optical interface may be distributed across an upper surface of the porch section. Such architectures may allow for full functional, at-speed testing of the memory device 110 using the native interface (e.g., the optical interface), for example by using an optical testing probe positioned above the optical interface.

Although described in the context of a DRAM memory system, one skilled in the art may appreciate that the described techniques and architectures may be applied to other types of memory systems, such as a RAM, ROM, SDRAM, SRAM, FeRAM, flash memory, PCM, self-selecting memory, chalcogenide memory technologies, NOR, or a NAND memory system.

FIG. 2 illustrates an example of a memory die 200 that supports near memory photonics in accordance with examples as disclosed herein. The memory die 200 may be an example of the memory dies 160 described with reference to FIG. 1. In some examples, the memory die 200 may be referred to as a memory chip, a memory device, or an electronic memory apparatus. The memory die 200 may include one or more memory cells 205 that may be programmable to store different logic states (e.g., programmed to one of a set of two or more possible states). For example, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). In some examples, the memory cells 205 may be arranged in an array, such as a memory array 170 described with reference to FIG. 1.

In some examples, a memory cell 205 may store a charge representative of the programmable states in a capacitor. DRAM architectures may include a capacitor that includes a dielectric material to store a charge representative of the programmable state. In other memory architectures, other storage devices and components are possible. For example, nonlinear dielectric materials may be employed. The memory cell 205 may include a logic storage component, such as capacitor 230, and a switching component 235 (e.g., a cell selection component). The capacitor 230 may be an example of a dielectric capacitor or a ferroelectric capacitor. A node of the capacitor 230 may be coupled with a voltage source 240, which may be the cell plate reference voltage, such as Vpl, or may be ground, such as Vss.

The memory die 200 may include access lines (e.g., word lines 210, digit lines 215) arranged in a pattern, such as a grid-like pattern. An access line may be a conductive line coupled with a memory cell 205 and may be used to perform access operations on the memory cell 205. In some examples, word lines 210 may be referred to as row lines. In some examples, digit lines 215 may be referred to as column lines or bit lines. References to access lines, row lines, column lines, word lines, digit lines, or bit lines, or their analogues, are interchangeable without loss of understanding. Memory cells 205 may be positioned at intersections of the word lines 210 and the digit lines 215.

Operations such as reading and writing may be performed on the memory cells 205 by activating access lines such as a word line 210 or a digit line 215. By biasing a word line 210 and a digit line 215 (e.g., applying a voltage to the word line 210 or the digit line 215), a single memory cell 205 may be accessed at their intersection. The intersection of a word line 210 and a digit line 215 in a two-dimensional or in a three-dimensional configuration may be referred to as an address of a memory cell 205. Activating a word line 210 or a digit line 215 may include applying a voltage to the respective line.

Accessing the memory cells 205 may be controlled through a row decoder 220, or a column decoder 225, or any combination thereof. For example, a row decoder 220 may receive a row address from the local memory controller 260 and activate a word line 210 based on the received row address. A column decoder 225 may receive a column address from the local memory controller 260 and may activate a digit line 215 based on the received column address.

Selecting or deselecting the memory cell 205 may be accomplished by activating or deactivating the switching component 235 using a word line 210. The capacitor 230 may be coupled with the digit line 215 using the switching component 235. For example, the capacitor 230 may be isolated from digit line 215 when the switching component 235 is deactivated, and the capacitor 230 may be coupled with digit line 215 when the switching component 235 is activated.

The sense component 245 may be operable to detect a state (e.g., a charge) stored on the capacitor 230 of the memory cell 205 and determine a logic state of the memory cell 205 based on the stored state. The sense component 245 may include one or more sense amplifiers to amplify or otherwise convert a signal resulting from accessing the memory cell 205. The sense component 245 may compare a signal detected from the memory cell 205 to a reference 250 (e.g., a reference voltage). The detected logic state of the memory cell 205 may be provided as an output of the sense component 245 (e.g., to an input/output 255), and may indicate the detected logic state to another component of a memory device (e.g., a memory device 110) that includes the memory die 200.

The local memory controller 260 may control the accessing of memory cells 205 through the various components (e.g., row decoder 220, column decoder 225, sense component 245). The local memory controller 260 may be an example of the local memory controller 165 described with reference to FIG. 1. In some examples, one or more of the row decoder 220, column decoder 225, and sense component 245 may be co-located with the local memory controller 260. The local memory controller 260 may be operable to receive one or more of commands or data from one or more different memory controllers (e.g., an external memory controller 120 associated with a host device 105, another controller associated with the memory die 200), translate the commands or the data (or both) into information that can be used by the memory die 200, perform one or more operations on the memory die 200, and communicate data from the memory die 200 to a host (e.g., a host device 105) based on performing the one or more operations. The local memory controller 260 may generate row signals and column address signals to activate the target word line 210 and the target digit line 215. The local memory controller 260 also may generate and control various signals (e.g., voltages, currents) used during the operation of the memory die 200. In general, the amplitude, the shape, or the duration of an applied voltage or current discussed herein may be varied and may be different for the various operations discussed in operating the memory die 200.

The local memory controller 260 may be operable to perform one or more access operations on one or more memory cells 205 of the memory die 200. Examples of access operations may include a write operation, a read operation, a refresh operation, a precharge operation, or an activate operation, among others. In some examples, access operations may be performed by or otherwise coordinated by the local memory controller 260 in response to various access commands (e.g., from a host device 105). The local memory controller 260 may be operable to perform other access operations not listed here or other operations related to the operating of the memory die 200 that are not directly related to accessing the memory cells 205.

In some cases, a memory die 200 may be included in a stack of memory dies 200, which may be coupled with an optical interface to convert between electrical signaling and optical signaling. For example, a set of memory dies 200 may be stacked vertically above a substrate, and may be coupled with an interface component which includes the optical interface. The optical interface may include an array of optical receivers and optical emitters, which may convert electrical signaling from a set of channels of each memory die 200 to optical signaling. The optical signaling may be carried over one or more optical channels to a host device, and the host device may include an optical interface to convert the optical signaling back to electrical signaling. Similarly, the optical interface may receive optical signaling from the host device over the optical channels, and convert the optical signaling to electrical signaling. In some examples, the stack of memory dies 200 may include a set of optical vias, each optical via extending vertically through a respective subset of the memory dies to couple (e.g., optically couple) a memory die with the interface component.

In some examples, the interface component may be positioned above the vertical stack of memory dies 200, and the optical interface may be distributed across the upper surface of the interface component. Alternatively, the interface component may be positioned below the stack of memory dies 200 (e.g., between the stack of memory dies and the substrate), and may extend horizontally beyond the stack of memory dies, forming a porch section. In such cases, the optical interface may be distributed across an upper surface of the porch section. Such architectures may allow for full functional, at-speed testing of the memory dies 200 using the native interface (e.g., the optical interface), for example by using an optical testing probe positioned above the optical interface.

Although described in the context of a DRAM memory system, one skilled in the art may appreciate that the described techniques and architectures may be applied to other types of memory systems, such as a RAM, ROM, SDRAM, SRAM, FeRAM, flash memory, PCM, self-selecting memory, chalcogenide memory technologies, NOR, or a NAND memory system.

FIGS. 3A and 3B illustrate examples of systems 300 and 301 that supports near memory photonics in accordance with examples as disclosed herein. For example, the system 300 and the system 301 may each include a host device 305, which may be an example of the host device 105 as described with reference to FIG. 1, and one or more vertical stacks 315 of memory dies 310, which may be examples of the memory dies 160, the memory die 200, or both as described with reference to FIGS. 1 and 2, arranged on a substrate 320.

A vertical stack 315 may be an example of a high-bandwidth memory (HBM) stack, and may include one or more layers of memory dies 310 arranged above the substrate 320. In some examples, the substrate 320 may be an example of a printed circuit board (PCB) or other layer on which the vertical stack 315 and the host device 305 may be positioned.

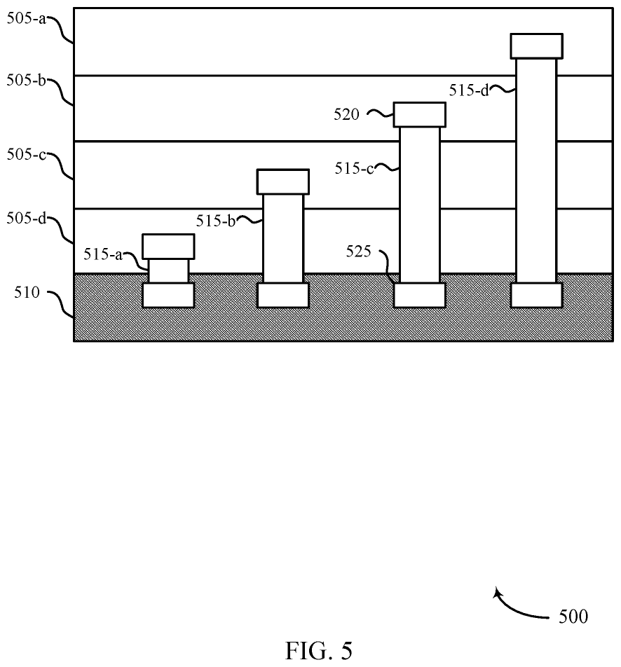

Each memory die 310 may include one or more input/output components which support communication of signaling with an interface component 325. For example, the vertical stack 315 may include one or more channels, such as through-silicon vias (TSVs), extending from a memory die 310 through the stack 315 to the interface component 325. The one or more channels may include an electrical path to support communication of electrical signals between a transceiver of the interface component 325 (e.g., the host device 305 coupled with the interface component 325) and the memory dies 310. Additionally or alternatively the one or more channels may be examples of optical vias which carry optical signaling, as described in greater detail with reference to FIGS. 5 through 7.

Some HBM stacks may include electrical connections between a host device and the HBM stack. In some cases, a silicon interposer may be used to multiplex HBM stacks with a host device. For example, a silicon interposer may include serializer-deserializer (serdes) functionality for communication over an electrical (e.g., serial) interface with the host and multiple memory interfaces for communication with multiple HBM stacks. A size of the interposer may be constrained by a quantity of memory interface channels, and thus may be relatively expensive. The HBM stack may include an electrical interface (e.g., as part of the interface component 325) to communicate signaling between memory dies of the HBM stack and the host device (e.g., via the silicon interposer). However, because of the quantity of channels used to support signaling, the set of conductive channels may have a fine pitch, which may cause interference between concurrently signals communicated signals (e.g., cross-talk interference). Further, to mitigate signal loss and degradation, such conductive channels may be relatively short, and may be of a similar length, which may limit architectural design options for the host device and the HBM stacks.

Additionally, to test an HBM stack using the electrical interface, a test probe may be attached to the electrical interface (e.g., a contact pad of the interface) to support communication of testing signals. However, attaching the probe may damage the interface (e.g., by leaving witness marks on the electrical interface), which may increase difficulty (e.g., increase the probability of manufacturing defects) of attaching a bond wire to couple the electrical interface with the set of conductive channels.

According to aspects described herein, an interface component 325 of a vertical stack 315 may include an optical interface 330-a to support communication of signaling between the memory dies 310 of the vertical stack 315 and the host device 305. Additionally, the host device 305 may include an optical interface 330-b to support such signaling. In some cases, the interface component 325 may include input/output circuitry (e.g., the optical interface 330), testing circuitry such as a built-in self-test (BIST) engine, or both.

An optical interface 330 may include a transceiver, such as a set of optical receivers and optical emitters configured to receive and send optical signaling (e.g., pulses of electromagnetic radiation), as well as convert between electrical signals communicated with the memory dies 310 and optical signals communicated over one or more optical channels 335. An optical emitter may be a light-emitting diode (LED) or laser diode, for example a gallium nitride (GaN) microLED, gallium arsenide (GaAs) laser, or vertical-cavity surface-emitting laser (VCSEL), although one skilled in the art may appreciate that other types of LEDs or lasers are possible. An optical receiver may be an example of a photodetector, and may be integrated directly into a substrate, such as a complimentary metal-oxide-semiconductor (CMOS) substrate. For example, a photodetector may be an example of a gateless transistor configured to transition between a conducting and non-conducting state in response to incident electromagnetic radiation (e.g., a light pulse from one or more optical emitters).

Because the photodetectors and emitters of an optical interface 330 may be implemented in a substrate such as a CMOS or GaAs substrate, an optical interface 330 may accordingly be monolithically integrated at either end of the communication link (e.g., at the host device 305 and the vertical stack 315). Additionally, the optical interface 330 may not include a dedicated power supply channel. Instead, the vertical stack 315 may receive power from a separate electrical channel, such as a channel interposed on or extending through the substrate 320 (e.g., connected to each of the memory dies 310 of the vertical stack 315 using TSVs).

In some cases, such as the system 300 illustrated in FIG. 3A, an interface component 325-a may be positioned on the top of a vertical stack 315-a (e.g., the interface component 325-a may be an upper layer of the vertical stack 315-a). In such cases, the optical interface 330-a may be distributed across (e.g., in a one-dimensional or two-dimensional array of elements) the upper surface of the interface component 325-a. In other cases, such as the system 301 illustrated in FIG. 3B, an interface component 325-b may be positioned on the bottom of the vertical stack 315-b, such that the interface component 325-b may be between the memory dies 310 of the vertical stack 315 and the substrate 320. In such cases, the interface component 325-b may include a porch 340, which may be a portion of the interface component 325-b that extends beyond the footprint of the vertical stack 315 in at least one horizontal direction. The optical interface 330-c may be distributed across the porch 340 (e.g., on an upper surface of the porch 340).

To support communication of optical signals between the optical interface 330-a and the optical interface 330-b, the system 300 may include a set of optical channels 335. In some examples, an optical channel 335 may include a multicore fiber optic cable to carry optical signals (e.g., light pulses) between the optical interface 330-b of the host device and the optical interface 330-a of the vertical stack 315. The multicore fiber optic cable may include multiple fiber optic cores, which may each carry a signal from one or more optical emitters, (e.g., of the optical interface 330-a), to one or more corresponding optical receivers (e.g., of the optical interface 330-b). To support the architecture of an optical channel 335, the optical emitters and optical receives of an optical interface 330 may be arranged in an array (e.g., a rectangular array, a hexagonal array), which may be distributed across the interface component 325 or the porch 340 thereof.

Because the set of optical channels 335 may mitigate or eliminate signal loss or cross-talk interference, the set of optical channels 335 between the host device 305 and the vertical stacks 315 may allow for more flexible system architecture, relative to a system which implements electrical channels. For example, the system 300, the system 301, or both may support multiple rows of vertical stacks 315 with variable distances to the host device 305. That is, the system 300, the system 301, or both may include the vertical stack 315-a or 315-b located a distance 345 from the host device 305, as well as a second vertical stack 315-c or 315-d located a distance 350, larger than the distance 345, from the host device 305.

Additionally, the system 300, the system 301, or both may include multiple host devices 305 (e.g., multiple processors) coupled with each of the vertical stacks 315. In such cases, the multiple host devices 305 may implement memory pooling techniques to share access to the vertical stacks 315. Although depicted as arranged on a same substrate 320, the host device 305 and the vertical stacks 315 may be arranged on separate substrates (e.g., the host device 305 and the vertical stacks 315 may be included in separate packages). Such architectures may allow for increased memory density by supporting a larger quantity of vertical stacks 315.

Additionally, the optical interface 330 may support full-functional touchless testing of the vertical stack 315. In some cases, the vertical stack 315 may communicate testing signals with a testing device. The testing device may include an optical testing interface, which may be communicatively coupled with the optical interface 330. For example, the testing device and the vertical stack 315 may be arranged such that the optical testing interface may be aligned with the optical interface 330. That is, optical emitters of the optical interface 330 may align with optical receivers of the optical testing interface, such that a signal from an optical emitter propagates directly to a corresponding optical receiver of the optical testing interface, and optical receivers of the optical interface 330 may align with optical transmitters of the optical testing interface, such that a signal from an optical transmitter of the optical testing interface propagates directly to a corresponding optical receiver of the optical interface 330. In some cases, the optical testing interface may include fiber optics, lensing, or other optical structures that may couple the optical transmitters and receivers of the optical testing interface to the optical interface 330 of the vertical stack 315 without touching the vertical stack 315. Such a testing technique may be referred to as touchless testing, and may allow for full functional testing of the vertical stack 315 using the native interface of the vertical stack 315 (e.g., the optical interface 330). Functional testing of the vertical stack 315 may be performed prior to attaching the vertical stack 315 to the substrate 320, or may be performed after the vertical stack 315 has been attached to the substrate 320) (e.g., prior to attaching the optical channels 335).

In some cases, a quantity of channels of the optical test probe need not be the same as the quantity of channels of the optical channel 335. For example, a quantity of optical channels (e.g., emitters, photodetectors, fiber optic cores) of the optical test probe may be larger than a quantity of optical channels (e.g., emitters, photodetectors), and may accordingly transmit a same signal from one or more emitters to one optical receiver, as well as receive a signal from a single emitter at multiple photodetectors.

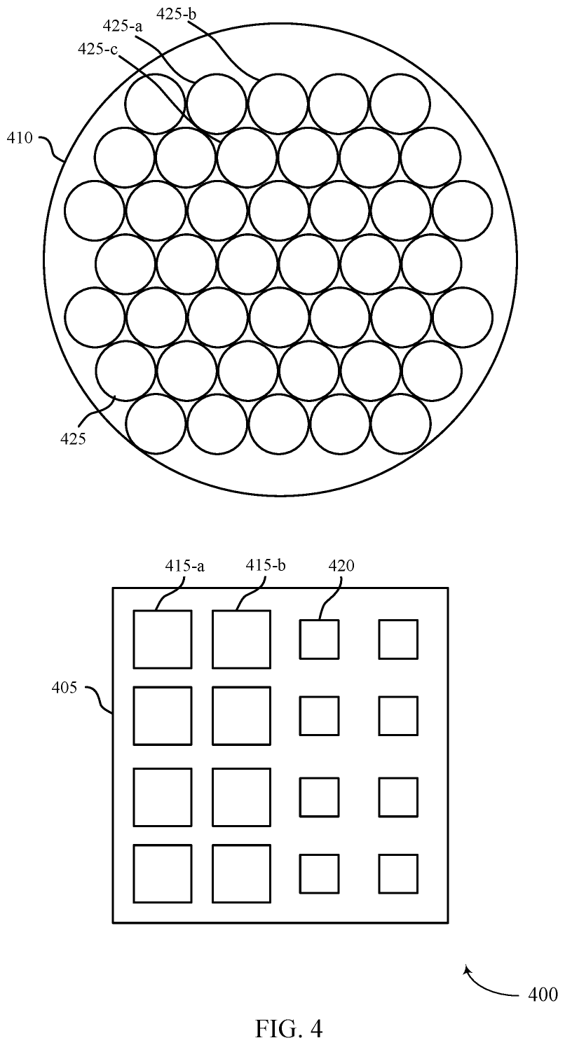

FIG. 4 illustrates an example of a system 400 that supports near memory photonics in accordance with examples as disclosed herein. For example, the system 400 may illustrate a top-down view of an optical interface 405 and a cross-sectional view of a fiber optic cable 410, which may each be examples of the corresponding entities as described with reference to FIGS. 3A and 3B.

The optical interface 405 may include a set of optical receivers 415, which may be examples of photodetectors, and a set of optical emitters 420, which may be examples of LEDs or lasers, as described with reference to FIGS. 3A and 3B. In some examples, the set of optical receivers 415 and the set of optical emitters 420 may each be arranged in an array, such as a rectangular grid as depicted in FIG. 4. Alternatively, the set of optical receivers 415 and the set of optical emitters 420 may be disposed in other arrangements, such as in a hexagonal grid. An array of optical receivers 415 may be disposed on one side of the optical interface 405, with an array of optical emitters 420 disposed on the other side of the optical interface 405, as illustrated in FIG. 4, or the array of optical receivers 415 and the array of optical emitters 420 may be interspersed (e.g., the optical interface 405 may include an alternating arrangement of optical receivers 415 and optical emitters 420).

The fiber optic cable 410 may include multiple optical fiber cores 425 (e.g., the fiber optic cable 410 may be a multicore optical fiber). In some examples, each optical fiber core 425 may correspond to a single optical channel, and the set of optical channels (e.g., the fiber optic cable 410) may communicate multiple signals concurrently using the optical fibers 425, for example as part of a multimode of a multicore optical fiber. Additionally or alternatively, each optical fiber 425 or a subset of the optical fibers 425 may correspond to a single channel, and the set of optical channels (e.g., the fiber optic cable 410) may communicate a single signal at a time, for example as part of a single mode of the multicore optical fiber. In some examples, the optical fibers 425 may be arranged in a rectangular grid, as depicted in FIG. 4, or may be arranged in a hexagonal grid. Each optical fiber core 425 may align with a respective optical receiver 415 or optical emitter 420 of the optical interface 405, or the optical fiber cores 425 may be offset or unaligned with the set of optical receivers 415 and the set of optical emitters 420.

For example, a quantity of the optical fiber cores 425 may be different (e.g., greater) than a quantity of the set of optical receivers 415 and the set of optical emitters 420. In such cases, one or more optical fiber cores 425 may route a same signal to an optical receiver 415, or one or more optical fiber cores 425 may receive signals from a single optical emitter 420. In one example, fiber optic cores 425-a, 425-b, and 425-c all carry a signal for photodetector 415-b when fiber optic cable 410 is used with optical interface 405.

In some examples, a tester may use a fiber optic cable 410 having a greater quantity of fiber optic cores 425 than the quantity of optical receivers 415 and optical emitters 420 of the optical interface 405. For example, a tester may have an arrangement of optical receivers and optical emitters that are denser or larger than the arrays of optical receivers 415 and optical emitters 420 of optical interface 405.

FIG. 5 illustrates an example of a stack of memory dies 500 that supports near memory photonics in accordance with examples as disclosed herein. The stack of memory dies 500 may include aspects of the vertical stack 315 as described with reference to FIG. 3. For example, the stack of memory dies 500 may include one or more memory dies 505 arranged in a vertical stack and an interface component 510, which may each be examples of the corresponding entities as described with reference to FIGS. 1 through 3B. In some examples, the stack of memory dies 500 may include a gap (e.g., an air gap, a gap filled with a dielectric material) between adjacent memory dies 505. Alternatively, adjacent memory dies 505 may be in contact, such as being hybrid bonded.

Each memory die 505 may communicate signals with the interface component 510 using a respective optical via 515, which may extend through one or more memory dies 505 to the interface component 510. Each optical via 515 may extend from a memory die 505 through memory dies 505 positioned below the memory die 505. For example, the optical via 515-a may extend from the memory die 505-a through the memory dies 505-b, 505-c, and 505-d to the interface component 510, the optical via 515-b may extend from the memory die 505-b through the memory dies 505-c and 505-d to the interface component 510, the optical via 515-c may extend from the memory die 505-c through the memory 505-d to the interface component 510, and the optical via 515-d may extend directly to the interface component 510 (e.g., the optical via 515-d may not extend through a memory die 505.

A memory die 505 may include a terminal 520, for example as part of an input/output component, to convert between electrical signals associated with the memory die 505 to optical signals to communicate over an optical via 515. In some examples, a terminal 520 may include one or more optical receivers and optical emitters (e.g., an array of photodetectors and optical emitters) to convert between electrical signaling and optical signaling. The interface component 510 may include a set of terminals 525 corresponding to terminals 520 of the memory dies 505. A terminal 525 may include aspects of a terminal 520, such as an array of optical receivers and optical emitters to convert between electrical signaling and optical signaling.

An optical via 515 may be an example of a pathway capable of carrying optical signals. For example, an optical via 515 may include a hollow (e.g., air-filled) cavity extending from a terminal 520 to a terminal 525. Alternatively, an optical via 515 may include a translucent material, which may allow propagation of optical signals while providing mechanical support to the memory dies 505. In such examples, an optical via 515 may operate in a single mode, and may thus communicate signals serially. To support serial communication, a terminal 520) and a terminal 525 may include a multiplexer to select a single signal at a time from multiple channels of a memory die 505 and the interface component 510. Additionally or alternatively, an optical via 515 may include multiple optical fibers (e.g., a multicore optical fiber). In such cases, the optical via may communicate multiple signals between channels of the memory die 505 and the interface component 510 concurrently (e.g., with each signal being carried using a respective optical fiber core).

In some examples, each memory die 505 may have a same or similar design, and the separate configurations depicted in FIG. 5 may be achieved by rotating the memory dies 505 with respect to each other. For example, a square memory die 505 may include a terminal 520) and three regions configured as portions of an optical via 515, with the terminal 520) and three regions disposed on corners of a square on the memory die 505. Additionally or alternatively, the memory dies 505 may be offset, such that each memory die 505 overhangs the memory die 505 directly below (e.g., the memory dies 505 may be “shingled”).

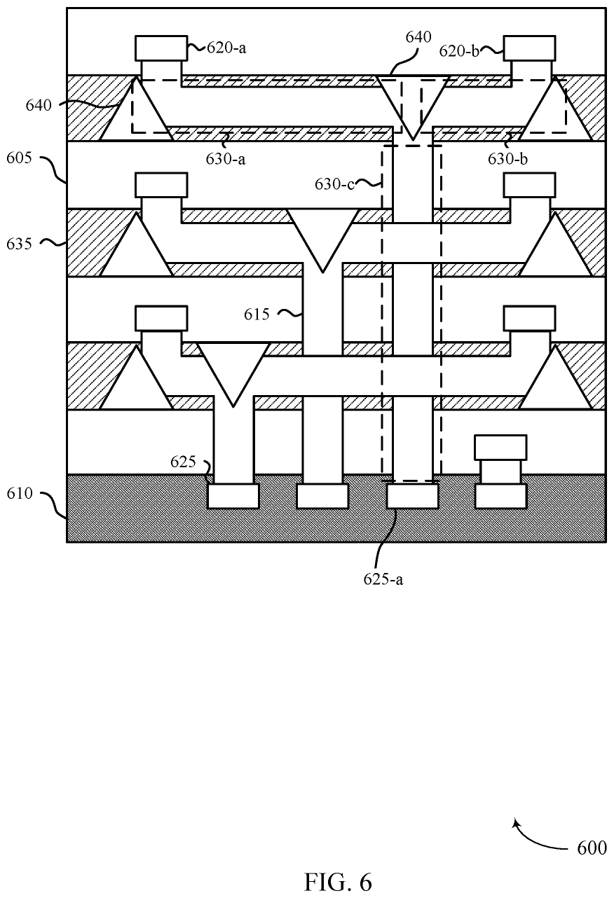

FIG. 6 illustrates an example of a stack of memory dies 600 that supports near memory photonics in accordance with examples as disclosed herein. The stack of memory dies 600 may include aspects of the vertical stack 315, the stack of memory dies 500, or both as described with reference to FIGS. 3 and 5. For example, the stack of memory dies 600 may include one or more memory dies 605 arranged in a vertical stack and configured to communicate with an interface component 610 using optical vias 615, terminals 620, and terminals 625, which may each be examples of the corresponding entities as described with reference to FIGS. 1 through 5. In some examples, the stack of memory dies 600 may include an underfill material 635 between adjacent memory dies 605, which may include a dielectric material or a translucent material to support one or more optical vias 615.

Each memory die 605 may communicate signals of the interface component 610 using an optical via 615 extending from a respective plurality of terminals 620, such as a terminal 620-a and a terminal 620-b, to a terminal 625-a. The terminal 620-a and the terminal 620-b may both be configured to convert between electrical signaling for a memory die 605 and optical signaling carried over an optical via 615.

To communicate signals from multiple terminals 620 of a memory die 605 to a single terminal 625 of the interface component, an optical via 615 may include multiple “legs” extending through the stack of memory dies 600. For example, an optical via 615 may include a first leg 630-a and a second leg 630-b extending horizontally through a layer of underfill material 635. Each layer of underfill material 635 may include one or more reflectors 640, which may be examples of mirrors or microelectromechanical systems (MEMS) reflectors, which may route optical signals between the terminals 620 and a terminal 625, for example through a third leg 630-c extending vertically through one or more memory dies 605, for example as part of a point-to-2point architecture. In some examples, the third legs 630-c of each optical via 615 may be disposed over a central portion of the interface component 610, and may thus extend through a central portion (e.g., a “spine”) of the memory dies 605. Such an architecture may contain perforations associated with the optical vias 615 to the spine of the memory dies 605, which may improve manufacturing yield and reduce may reduce on-die data movement for a memory die 605. In some examples, the reflectors 640 may be configured to steer optical signals towards one or the other of the terminals 620. For example, reflector 640 may steer optical signals between terminal 625-a and 620-a, or may steer optical signals between terminal 625-a and 620-b.

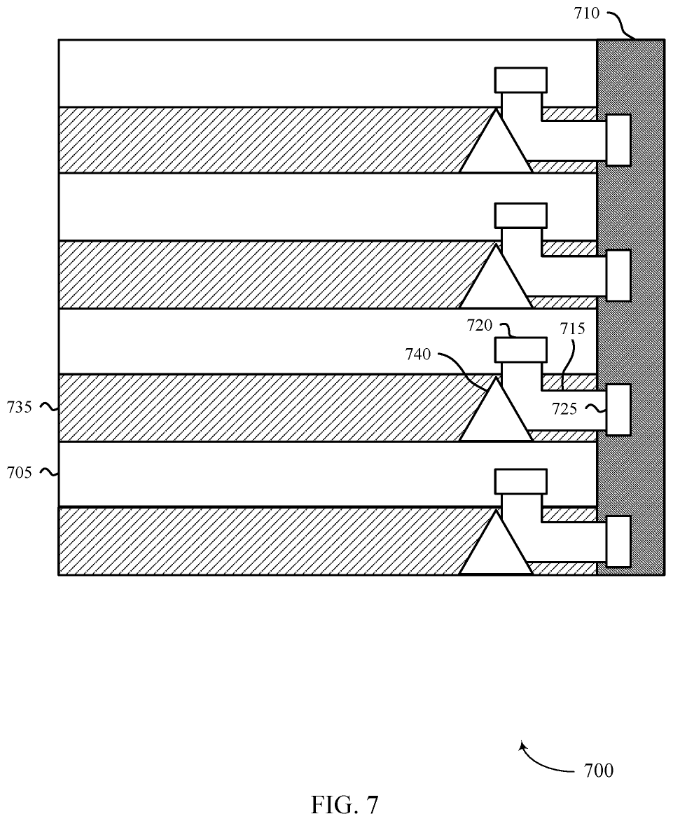

FIG. 7 illustrates an example of a stack of memory dies 700 that supports near memory photonics in accordance with examples as disclosed herein. The stack of memory dies 700 may include aspects of the vertical stack 315 as described with reference to FIG. 3. For example, the stack of memory dies 700 may include one or more memory dies 705 arranged in a vertical stack and an interface component 710 using optical vias 715, terminals 720, and terminals 725, which may each be examples of the corresponding entities as described with reference to FIGS. 1 through 6. In some examples, the stack of memory dies 700 may include an underfill material 735 between adjacent memory dies 705, which may include a dielectric material or a translucent material to support one or more optical vias 715.

The example depicted in FIG. 7 may illustrate an architecture in which an interface component 710 may be positioned on a sidewall of the stack of memory dies 700. For example, the interface component 710 may be positioned adjacent to an edge of each memory die 605. In such an architecture, each memory die 705 may communicate signals of the interface component 710 using an optical via 715 extending horizontally from a terminal 720 to a respective terminal 725 of the interface component 710. To communicate signals from a terminal 720 of a memory die 705 to a terminal 725 of the interface component, an optical via 715 may include a reflector 740 (e.g., a MEMS), which may route optical signals between the terminal 720 and a terminal 725

An apparatus is described. The following provides an overview of aspects of the apparatus as described herein:

Aspect 1: An apparatus, including: a plurality of memory dies arranged in a vertical stack; and an interface component disposed above the plurality of memory dies and including: a plurality of first transceivers coupled with the plurality of memory dies via respective sets of first channels, the plurality of first transceivers configured to communicate first signaling via the respective sets of first channels; and a second transceiver configured to communicate second signaling via a set of second channels, the set of second channels being optical channels, where the interface component is configured to convert between the first signaling and the second signaling.

Aspect 2: The apparatus of aspect 1, where a memory subsystem includes the plurality of memory dies and the interface component, the apparatus further including: a substrate, where the memory subsystem is disposed on the substrate; an optical fiber including a plurality of optical fiber cores, where the set of second channels include the optical fiber; and a processor disposed on the substrate and configured to communicate the second signaling with the second transceiver of the interface component of the memory subsystem using the set of second channels.

Aspect 3: The apparatus of aspect 2, where the second transceiver includes an array of photodetector terminals configured to convert optical signaling to electrical signaling.

Aspect 4: The apparatus of aspect 3, where a quantity of the plurality of optical fiber cores is greater than a quantity of the photodetector terminals of the array.

Aspect 5: The apparatus of any of aspects 2 through 4, where the second transceiver includes an array of light emitting terminals configured to convert electrical signaling to optical signaling.

Aspect 6: The apparatus of aspect 5, where a quantity of the plurality of optical fiber cores is greater than a quantity of the light emitting terminals of the array.

Aspect 7: The apparatus of any of aspects 1 through 6, where the plurality of memory dies includes: a plurality of conductive vias, each conductive via extending vertically through at least a subset of the plurality of memory dies and configured to carry electrical signaling between a respective memory die and the interface component.

Aspect 8: The apparatus of any of aspects 1 through 7, where the plurality of memory dies includes: a plurality of optical vias, each optical via extending vertically through at least a subset of the plurality of memory dies and configured to carry optical signaling between a respective memory die and the interface component.

Aspect 9: The apparatus of any of aspects 1 through 8, where the plurality of memory dies receive power via a third channel separate from the respective sets of first channels and the set of second channels.

Aspect 10: The apparatus of any of aspects 1 through 9, where the respective sets of first channels are conductive channels, such that the plurality of first transceivers are electrically coupled with the plurality of memory dies.

Aspect 11: The apparatus of any of aspects 1 through 10, where the respective sets of first channels are optical channels, such that the plurality of first transceivers are optically coupled with the plurality of memory dies.

An apparatus is described. The following provides an overview of aspects of the apparatus as described herein:

Aspect 12: An apparatus, including: a plurality of memory dies arranged in a vertical stack; and an interface component disposed below the plurality of memory dies and including: a plurality of first transceivers coupled with the plurality of memory dies via respective sets of first channels, the plurality of first transceivers configured to communicate first signaling via the respective sets of first channels; and a second transceiver configured to communicate second signaling via a set of second channels, the second transceiver including a terminal disposed on a portion of the interface component that extends horizontally from the vertical stack of the plurality of memory dies, and the set of second channels being optical channels, where the interface component is configured to convert between the first signaling and the second signaling.

Aspect 13: The apparatus of aspect 12, where a memory subsystem includes the plurality of memory dies and the interface component, the apparatus further including: a substrate, where the memory subsystem is disposed on the substrate: an optical fiber including a plurality of optical fiber cores, where the set of second channels include the optical fiber; and a processor disposed on the substrate and configured to communicate the second signaling with the second transceiver of the interface component of the memory subsystem using the set of second channels.

Aspect 14: The apparatus of aspect 13, where the terminal includes an array of photodetector terminals configured to convert optical signaling to electrical signaling, the array of photodetector terminals.

Aspect 15: The apparatus of aspect 14, where a quantity of the plurality of optical fiber cores is greater than a quantity of the photodetector terminals of the array.

Aspect 16: The apparatus of any of aspects 13 through 15, where the terminal includes an array of light emitting terminals configured to convert electrical signaling to optical signaling.

An apparatus is described. The following provides an overview of aspects of the apparatus as described herein:

Aspect 17: An apparatus, including: an interface component including a set of first terminals configured to communicate optical signaling: a plurality of memory dies arranged in vertical stack above the interface component, each memory die of the plurality including a respective second terminal configured to communicate the optical signaling; and a plurality of optical vias each extending vertically through at least a subset of the plurality of memory dies, and each configured to carry the optical signaling between the respective second terminal of each memory die and a corresponding first terminal of the set of first terminals of the interface component.

Aspect 18: The apparatus of aspect 17, where a second terminal of a memory die of the plurality of memory dies is coupled with a multiplexer configured to selectively output electrical signaling from a plurality of memory channels of the memory die.

Aspect 19: The apparatus of any of aspects 17 through 18, where an optical via of the plurality of optical vias includes a plurality of optical fibers, each optical fiber configured to carry the optical signaling between a respective second terminal of a plurality of second terminals of a memory die associated with the optical via.

Aspect 20: The apparatus of aspect 19, where each second terminal of the plurality of second terminals of the memory die is configured to convert between the optical signaling and first electrical signaling associated with a respective memory channel of a plurality of memory channels of the memory die.

Aspect 21: The apparatus of any of aspects 17 through 20, where each terminal of the set of first terminals and each second terminal includes a respective photodetector configured to convert the optical signaling to electrical signaling and a respective light emitter configured to convert electrical signaling to the optical signaling.

Aspect 22: The apparatus of any of aspects 17 through 21, where each optical via includes a void extending vertically through the subset of the plurality of memory dies corresponding to the optical via.

Aspect 23: The apparatus of any of aspects 17 through 22, where the interface component includes a transceiver configured to communicate second signaling with a processor external to the vertical stack.

Aspect 24: The apparatus of aspect 23, where the interface component is configured to convert between the second signaling and the optical signaling.

An apparatus is described. The following provides an overview of aspects of the apparatus as described herein:

Aspect 25: An apparatus, including: an interface component including a set of first terminals configured to convert between electrical signaling and optical signaling: a plurality of memory dies arranged in vertical stack above the interface component, each memory die of the plurality including a respective plurality of second terminals; and a plurality of optical vias each extending vertically through at least a subset of the plurality of memory dies, and each configured to carry optical signaling between two or more of the respective plurality of second terminals of a memory die of the plurality of memory dies and a corresponding first terminal of the set of first terminals of the interface component.

Aspect 26: The apparatus of aspect 25, further including: a plurality of layers of dielectric material, each layer between a respective pair of memory dies of the plurality of memory dies.

Aspect 27: The apparatus of aspect 26, where an optical via of the plurality of optical vias includes a first leg extending horizontally through a layer of dielectric material of the plurality of layers of dielectric material to one of the second terminals of the plurality of second terminals of a memory die of the plurality of memory dies, and the optical via includes a second leg extending horizontally through the layer of dielectric material to a different one of the second terminals of the plurality of second terminals of the memory die.

Aspect 28: The apparatus of aspect 27, where: the optical via further includes a third leg extending vertically through the subset of the plurality of memory dies corresponding to the optical via: the first leg includes a first reflector and a second reflector configured to route optical signaling between the corresponding first terminal and the one of the second terminals; and the second leg includes a third reflector and the second reflector configured to route optical signaling between the corresponding first terminal and the different one of the second terminals.

Aspect 29: The apparatus of any of aspects 25 through 28, where a second terminal of a memory die of the plurality of memory dies is coupled with a multiplexer configured to selectively output electrical signaling from a plurality of memory channels of the memory die.

Aspect 30: The apparatus of any of aspects 25 through 29, where an optical via of the plurality of optical vias includes a plurality of optical fibers, each optical fiber configured to carry optical signaling between a respective second terminal of a plurality of second terminals of a memory die associated with the optical via.

Aspect 31: The apparatus of aspect 30, where each second terminal of the plurality of second terminals of the memory die is configured to receive electrical signaling from a respective memory channel of a plurality of memory channels of the memory die.

An apparatus is described. The following provides an overview of aspects of the apparatus as described herein:

Aspect 32: An apparatus, including: a plurality of memory dies arranged in vertical stack, each memory die of the plurality including a respective first terminal configured to convert between electrical signaling and optical signaling: an interface component including a set of second terminals configured to convert between electrical signaling and optical signaling, the interface component adjacent to respective edges of the plurality of memory dies of the vertical stack; and a plurality of optical vias each extending horizontally between two of the plurality of memory dies, and each configured to carry optical signaling between the respective first terminal of a memory die and a corresponding second terminal of the set of second terminals of the interface component.

Aspect 33: The apparatus of aspect 32, further including: a plurality of layers of dielectric material, each layer between a respective pair of memory dies of the plurality of memory dies.

Aspect 34: The apparatus of aspect 33, where each optical via of the plurality of optical vias extends horizontally through a respective layer of dielectric material of the plurality of layers of dielectric material.

Aspect 35: The apparatus of any of aspects 32 through 34, where each optical via includes a reflector configured to route optical signaling to the corresponding second terminal.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal: however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The terms “layer” and “level” used herein refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily doped, degenerate) semiconductor region. The source and drain may be separated by a doped (e.g., lightly doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components.” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. An apparatus, comprising:
a plurality of memory dies arranged in a vertical stack; and
an interface component disposed above the plurality of memory dies and comprising:
a plurality of first transceivers coupled with the plurality of memory dies via respective sets of first channels, the plurality of first transceivers configured to communicate first signaling via the respective sets of first channels; and
a second transceiver configured to communicate second signaling via a set of second channels, the set of second channels being optical channels,
wherein the interface component is configured to convert between the first signaling and the second signaling.

2. The apparatus of claim 1, wherein a memory subsystem comprises the plurality of memory dies and the interface component, the apparatus further comprising:
a substrate, wherein the memory subsystem is disposed on the substrate;
an optical fiber comprising a plurality of optical fiber cores, wherein the set of second channels comprise the optical fiber; and
a processor disposed on the substrate and configured to communicate the second signaling with the second transceiver of the interface component of the memory subsystem using the set of second channels.

3. The apparatus of claim 2, wherein the second transceiver comprises an array of photodetector terminals configured to convert optical signaling to electrical signaling.

4. The apparatus of claim 3, wherein a quantity of the plurality of optical fiber cores is greater than a quantity of the photodetector terminals of the array.

5. The apparatus of claim 2, wherein the second transceiver comprises an array of light emitting terminals configured to convert electrical signaling to optical signaling.

6. The apparatus of claim 5, wherein a quantity of the plurality of optical fiber cores is greater than a quantity of the light emitting terminals of the array.

7. The apparatus of claim 1, wherein the plurality of memory dies comprises:
a plurality of conductive vias, each conductive via extending vertically through at least a subset of the plurality of memory dies and configured to carry electrical signaling between a respective memory die and the interface component.

8. The apparatus of claim 1, wherein the plurality of memory dies comprises:
a plurality of optical vias, each optical via extending vertically through at least a subset of the plurality of memory dies and configured to carry optical signaling between a respective memory die and the interface component.

9. The apparatus of claim 1, wherein the plurality of memory dies receive power via a third channel separate from the respective sets of first channels and the set of second channels.

10. An apparatus, comprising:
a plurality of memory dies arranged in a vertical stack; and
an interface component disposed below the plurality of memory dies and comprising:
a plurality of first transceivers coupled with the plurality of memory dies via respective sets of first channels, the plurality of first transceivers configured to communicate first signaling via the respective sets of first channels; and
a second transceiver configured to communicate second signaling via a set of second channels, the second transceiver comprising a terminal disposed on a portion of the interface component that extends horizontally from the vertical stack of the plurality of memory dies, and the set of second channels being optical channels,
wherein the interface component is configured to convert between the first signaling and the second signaling.

11. The apparatus of claim 10, wherein a memory subsystem comprises the plurality of memory dies and the interface component, the apparatus further comprising:
a substrate, wherein the memory subsystem is disposed on the substrate;
an optical fiber comprising a plurality of optical fiber cores, wherein the set of second channels comprise the optical fiber; and
a processor disposed on the substrate and configured to communicate the second signaling with the second transceiver of the interface component of the memory subsystem using the set of second channels.

12. The apparatus of claim 11, wherein the terminal comprises an array of photodetector terminals configured to convert optical signaling to electrical signaling, the array of photodetector terminals.

13. The apparatus of claim 12, wherein a quantity of the plurality of optical fiber cores is greater than a quantity of the photodetector terminals of the array.

14. The apparatus of claim 11, wherein the terminal comprises an array of light emitting terminals configured to convert electrical signaling to optical signaling.

15. An apparatus, comprising:
an interface component comprising a set of first terminals configured to communicate optical signaling;
a plurality of memory dies arranged in vertical stack above the interface component, each memory die of the plurality comprising a respective second terminal configured to communicate the optical signaling; and
a plurality of optical vias each extending vertically through at least a subset of the plurality of memory dies, and each configured to carry the optical signaling between the respective second terminal of each memory die and a corresponding first terminal of the set of first terminals of the interface component.

16. The apparatus of claim 15, wherein a second terminal of a memory die of the plurality of memory dies is coupled with a multiplexer configured to selectively output electrical signaling from a plurality of memory channels of the memory die.

17. The apparatus of claim 15, wherein an optical via of the plurality of optical vias comprises a plurality of optical fibers, each optical fiber configured to carry the optical signaling between a respective second terminal of a plurality of second terminals of a memory die associated with the optical via.

18. The apparatus of claim 17, wherein each second terminal of the plurality of second terminals of the memory die is configured to convert between the optical signaling and first electrical signaling associated with a respective memory channel of a plurality of memory channels of the memory die.

19. The apparatus of claim 15, wherein each terminal of the set of first terminals and each second terminal comprises a respective photodetector configured to convert the optical signaling to electrical signaling and a respective light emitter configured to convert electrical signaling to the optical signaling.

20. The apparatus of claim 15, wherein each optical via comprises a void extending vertically through the subset of the plurality of memory dies corresponding to the optical via.
